(19) United States
(12) Patent Application Publication
(10) Pub. No.: US 2013/0312663 A1
(43) Pub. Date: Nov. 28, 2013

(54) Vapor Delivery Apparatus

(71) Applicants: Mukul Khosla, San Jose, CA (US); Mike Grimes, San Jose, CA (US); Peter Krotov, San Jose, CA (US); Genny Epshteyn, San Jose, CA (US)

(72) Inventors: Mukul Khosla, San Jose, CA (US); Mike Grimes, San Jose, CA (US); Peter Krotov, San Jose, CA (US); Genny Epshteyn, San Jose, CA (US)

(73) Assignee: Applied Microstructures, Inc., San Jose, CA (US)

(21) Appl. No.: 13/477,928

(22) Filed: May 22, 2012

(51) Int. Cl. F17D 3/00; C23C 16/52

(52) U.S. Cl. 118/710; 137/334; 137/12

(57) ABSTRACT

A vapor delivery apparatus for providing a precursor vapor for a vapor deposition process includes a precursor container for holding a liquid or solid precursor. A first temperature control assembly maintains the precursor container at a first temperature to generate a vapor precursor from the liquid or solid precursor. An isolation valve is coupled to the precursor container, and a specific quantity of the vapor precursor is accumulated in an expansion volume. A fill valve, which is coupled to each of the isolation valve and the expansion volume, controls the flow of the vapor precursor from the precursor container into the expansion volume. A second temperature control assembly maintains the isolation valve at a second temperature greater than the first temperature.

### BACKGROUND

1. Field of the Invention

Embodiments of the present invention relate to a vapor delivery apparatus for molecular vapor deposition (MVD), atomic layer deposition (ALD), and chemical vapor deposition (CVD) applications.

2. Description of the Related Art

Vapor-phase deposition methods and apparatus for the application of layers and coatings on substrates are useful in the fabrication of electronic devices, micro-electromechanical systems (MEMS), bio-MEMS devices, and microfluidic devices, and semiconductor devices. One such coating formation method employs a batch-like addition and mixing of all of the reactants to be consumed in a coating formation process. The coating formation process may be complete after one step, or may include a number of individual steps, where different or repetitive reactive processes are carried out in each individual step. The apparatus used to carry out the method provides for the addition of a precise amount of each of the reactants to be consumed in a single reaction step of the coating formation process. The apparatus may provide for precise addition of quantities of different combinations of reactants during a single step or when there are a number of different individual steps in the coating formation process. The precise addition of each of the reactants is based on a metering system where the amount of reactant added in an individual step is carefully controlled. In particular, the reactant in vapor form is metered into an expansion volume with a predetermined set volume at a specified temperature to a specified pressure to provide a highly accurate amount of reactant. The entire measured amounts of each reactant are transferred in batch fashion into the process chamber in which the coating is formed. The order in which each reactant is added to the chamber for a given reaction step is selectable, and may depend on the relative reactivities of the reactants when there are more than one reactant, the need to have one reactant or the catalytic agent contact the substrate surface first, or a balancing of these considerations.

It is in this context that embodiments of the invention arise.

### SUMMARY

Embodiments of the present invention provide an improved vapor delivery apparatus and method for molecular vapor deposition (MVD), atomic layer deposition (ALD), and chemical vapor deposition (CVD) applications. Several embodiments of the present invention are described below.

In one embodiment a vapor delivery apparatus for providing a precursor vapor for a vapor deposition process is provided. The vapor delivery apparatus includes a precursor container for holding a liquid or solid precursor. A first temperature control assembly maintains the precursor container at a first temperature to generate a vapor precursor from the liquid or solid precursor. An isolation valve is coupled to the precursor container, and a specific quantity of the vapor precursor is accumulated in an expansion volume. A fill valve, which is coupled to each of the isolation valve and the expansion volume, controls the flow of the vapor precursor from the precursor container into the expansion volume. A second temperature control assembly maintains the isolation valve at a second temperature greater than the first temperature.

In one embodiment, the first temperature control assembly includes a first heating device for heating the precursor container, a first temperature detector for detecting temperature of the precursor container, and a first controller configured to apply power to the first heating device based on the detected temperature of the precursor container to maintain the precursor container at the first temperature. In this embodiment, the second temperature control assembly includes a second heating device for heating the isolation valve, a second temperature detector for detecting temperature of the isolation valve, and a second controller configured to apply power to the second heating device based on the detected temperature of the isolation valve to maintain the isolation valve at the second temperature.

In one embodiment, the first heating device includes a first heater jacket coupled to the precursor container, and the second heating device includes a second heater jacket coupled to the isolation valve.

In one embodiment, the first temperature detector and the second temperature detector each include either a thermocouple or a resistance temperature detector.

In one embodiment, the first controller and the second controller each include a solid state relay.

In one embodiment, the precursor container defines a volume of about 50 cc to about 5000 cc.

In one embodiment, the vapor delivery apparatus further includes a third temperature control assembly for maintaining the expansion volume at a third temperature greater than the second temperature.

In one embodiment, the third temperature control assembly includes a third heating device for heating the expansion volume, a third temperature detector for detecting temperature of the expansion volume, and a third controller configured to apply power to the third heating device based on the detected temperature of the expansion volume to maintain the expansion volume at the third temperature.

In one embodiment, the vapor delivery apparatus further includes a pressure sensor for detecting pressure in the expansion volume. A valve controller is configured to operate the fill valve based on the detected pressure in the expansion volume to accumulate the specific quantity of the vapor precursor in the expansion volume.

In one embodiment, the vapor delivery apparatus further includes a delivery valve coupled to the expansion volume, and the delivery valve controls the flow of the specific quantity of the vapor precursor from the expansion volume into a process chamber.

In another embodiment, a method for preparing a precursor vapor for a deposition process is provided. In this method, a precursor container is maintained at a first temperature to generate the vapor precursor from a liquid or solid precursor. An isolation valve, which is coupled to the precursor contained, is maintained at a second temperature greater than the first temperature. The pressure in an expansion volume is detected, and a fill valve is operated based on the detected pressure in the expansion volume to control flow of the vapor precursor from the precursor container into the expansion volume to accumulate a specific quantity of the vapor precursor. The fill valve is coupled to the isolation valve and to the expansion volume.

In one embodiment, the precursor container is maintained at the first temperature by detecting the temperature of the precursor container, and applying power to a first heating device based on the detected temperature of the precursor container. The isolation valve is maintained at the second temperature by detecting the temperature of the isolation valve, and applying power to a second heating device based on the detected temperature of the isolation valve.

In one embodiment, the method further includes maintaining the expansion volume at a third temperature greater than the second temperature.

In one embodiment, the expansion volume is maintained at the third temperature by detecting the temperature of the expansion volume, and applying power to a third heating device based on the detected temperature of the expansion volume.

In one embodiment, the method further includes operating a delivery valve to control flow of the specific quantity of the vapor precursor from the expansion volume into a process chamber.

In another embodiment, an atomic layer deposition system is provided. The atomic layer deposition system includes a precursor container for holding a liquid or solid precursor. A first temperature control assembly maintains the precursor container at a first temperature to generate a vapor precursor from the liquid or solid precursor. A specific quantity of the vapor precursor is accumulated in an expansion volume. A first control valve is disposed between the precursor container and the expansion volume, and the first control valve controls the flow of the vapor precursor from the precursor container into the expansion volume. A second temperature control assembly maintains the control valve at a second temperature greater than the first temperature, and a third temperature control assembly maintains the expansion volume at a third temperature greater than the second temperature. A pressure sensor detects pressure in the expansion volume, and a valve controller is configured to operate the control valve based on the detected pressure in the expansion volume to accumulate the specific quantity of the vapor precursor in the expansion volume. The atomic layer deposition system also includes a process chamber, and a second control valve is disposed between the expansion volume and the process chamber. The second control valve controls the flow of the specific quantity of the vapor precursor from the expansion volume into the process chamber.

In one embodiment, the first temperature control assembly includes a first heating device for heating the precursor container, a first temperature detector for detecting temperature of the precursor container, and a first controller configured to apply power to the first heating device based on the detected temperature of the precursor container to maintain the precursor container at the first temperature. In this embodiment, the second temperature control assembly includes a second heating device for heating the first control valve, a second temperature detector for detecting temperature of the first control valve, and a second controller configured to apply power to the second heating device based on the detected temperature of the first control valve to maintain the first control valve at the second temperature. In this embodiment, the third temperature control assembly includes a third heating device for heating the expansion volume, a third temperature detector for detecting temperature of the expansion volume, and a third controller configured to apply power to the third heating device based on the detected temperature of the expansion volume to maintain the expansion volume at the third temperature.

In one embodiment, the first heating device includes a first heater jacket coupled to the precursor container; and the second heating device includes a second heater jacket coupled to the first control valve.

In one embodiment, each of the first, second, and third temperature detectors includes either a thermocouple or a resistance temperature detector.

In one embodiment, the precursor container defines a volume of about 50 cc to about 5,000 cc.

Other aspects of the invention will become apparent from the following detailed description, taken in conjunction with the accompanying drawings, illustrating by way of example the principles of the invention.

### BRIEF DESCRIPTION OF THE DRAWINGS

The invention may best be understood by reference to the following description taken in conjunction with the accompanying drawings in which:

FIG. 1 shows a cross-sectional schematic of a vapor deposition system 100 for vapor deposition of thin coatings, in accordance with embodiments of the invention.

FIG. 2 is a schematic of a conventional vapor delivery line for delivering a precursor vapor to a process chamber.

FIG. 3 illustrates the results of a computer simulation modeling the temperature of the isolation valve as a function of the percentage fill of the precursor storage container.

FIG. 4 is a schematic of a vapor delivery apparatus for providing precursor vapor to a process chamber for vapor deposition.

FIG. 5 is a graph illustrating fill time of the expansion volume as a function of isolation valve temperature.

FIG. 6 illustrates a method for preparing a precursor vapor for a deposition process, in accordance with embodiments of the invention.

### DETAILED DESCRIPTION

A vapor delivery apparatus and method are provided for molecular vapor deposition (MVD), atomic layer deposition (ALD), and chemical vapor deposition (CVD) applications. Several inventive embodiments are described below.

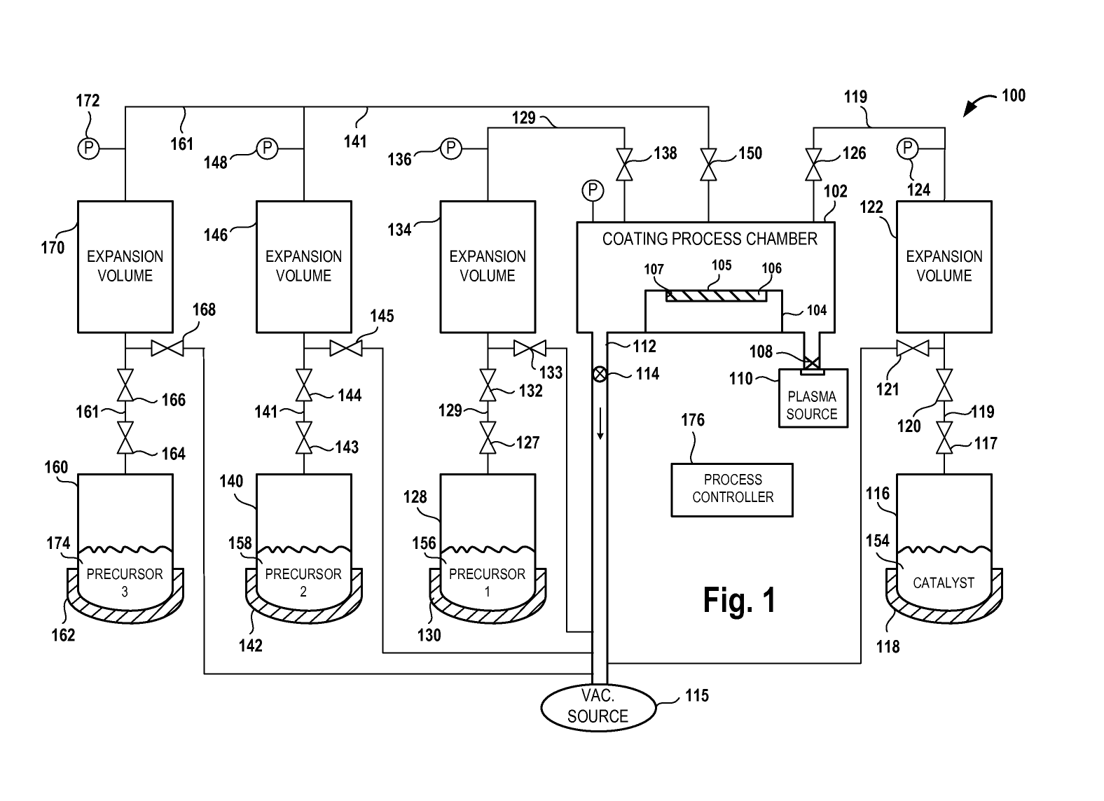

FIG. 1 shows a cross-sectional schematic of a vapor deposition system 100 for vapor deposition of thin coatings, in accordance with embodiments of the invention. The system 100 includes a process chamber 102 in which thin (typically 5 angstroms to 1,000 angstroms thick) coatings are vapor deposited. A substrate 106 to be coated rests upon a substrate holder 104, typically within a recess 107 in the substrate holder 104. Depending on the chamber design, the substrate 106 may rest on the chamber bottom (not shown in this position in FIG. 1). Attached to process chamber 102 is a remote plasma source 110, connected via a valve 108. Remote plasma source 110 may be used to provide a plasma which is used to clean and/or convert a substrate surface to a particular chemical state prior to application of a coating (which enables reaction of coating species and/or catalyst with the surface, thus improving adhesion and/or formation of the coating); or may be used to provide species helpful during formation of the coating or modifications of the coating after deposition. The plasma may be generated using a microwave, DC, or inductive RF power source, or combinations thereof. The process chamber 102 makes use of an exhaust port 112 for the removal of reaction byproducts and is opened for pumping/purging of the chamber 102. A shut-off valve or a control valve 114 is used to isolate the chamber or to control the amount of vacuum applied to the exhaust port from a vacuum source 115.

The system 100 shown in FIG. 1 is illustrative of a vapor deposited coating which employs three precursor materials and a catalyst. One skilled in the art will understand that one or more precursors and from zero to multiple catalysts may be used during vapor deposition of a coating. A catalyst storage container 116 contains catalyst 154, which may be heated using heater 118 to provide a vapor, as necessary. It is understood that precursor and catalyst storage container walls, and transfer lines into process chamber 102 will be heated as necessary to maintain a precursor or catalyst in a vaporous state, thereby minimizing or avoiding condensation. The same is true with respect to heating of the interior surfaces of process chamber 102 and the surface of substrate 106 to which the coating (not shown) is applied.

An isolation valve 117 and a fill valve 120 are present on transfer line 119 between catalyst storage container 116 and catalyst expansion volume 122, where the catalyst vapor is permitted to accumulate until a nominal, specified pressure is measured at pressure indicator 124. Filling of the catalyst expansion volume 122 is controlled by the fill valve 120, which is in a normally-closed position and returns to that position once the specified pressure is reached in catalyst expansion volume 122. At the time the catalyst vapor in expansion volume 122 is to be released, delivery valve 126 on transfer line 119 is opened to permit entrance of the catalyst present in expansion volume 122 into process chamber 102 which is at a lower pressure. Fill valve 120 and delivery valve 126 are controlled by a programmable process controller 176. A vacuum purge valve 121 taps a portion of the transfer line 119 between the fill valve 120 and the expansion volume 122. The vacuum purge valve 121 controls exposure to a vacuum source 115, and may be opened, for example, following a deposition operation to purge any remaining gases from the expansion volume 122.

Isolation valve 117 is manually controlled and prevents exposure of the contents of the storage container 116 to atmosphere during transport of the storage container. Broadly speaking, when the catalyst storage container 116 and the isolation valve 117 are connected to the system 100 (via line 119), the isolation valve 117 can be maintained in an open position to permit the vapor of the catalyst 154 from the catalyst storage container 116 to be made available for use by the system 100. The introduction of the catalyst vapor into the expansion volume 122 is controlled directly by the fill valve 120. However, when the storage container 116 is transported, such as may be required when the storage container 116 is first obtained or is being serviced or refilled, then the isolation valve 117 that is attached to the storage container 116 can be manually closed to prevent exposure to atmosphere.

The isolation valve 117 enables the storage container 116 to be transported and connected to the system without ever exposing the interior of the storage container to atmosphere, which prevents possible contamination from such exposure from occurring. Prior to first use after connection, with the isolation valve 117 maintained in a closed position, the region between the isolation valve 117 and the fill valve 120 can be vacuum purged by opening the vacuum purge valve 121 (which will also purge the expansion volume 122 as well). After vacuum purging, the fill valve 120 can then be closed and the isolation valve 117 opened, thereby setting these valves in their default configurations prior to vapor deposition operations.

A Precursor 1 storage container 128 contains coating reactant Precursor 1, which may be heated using heater 130 to provide a vapor, as necessary. As previously mentioned, Precursor 1 transfer line 129 and expansion volume 134 internal surfaces are heated as necessary to maintain a Precursor 1 in a vaporous state, thereby avoiding condensation. A fill valve 132 and isolation valve 127 are present on transfer line 129 between Precursor 1 storage container 128 and Precursor 1 expansion volume 134, where the Precursor 1 vapor is permitted to accumulate until a nominal, specified pressure is measured at pressure indicator 136. Fill valve 132 is in a normally-closed position and returns to that position once the specified pressure is reached in Precursor 1 expansion volume 134. At the time the Precursor 1 vapor in expansion volume 134 is to be released, valve 138 on transfer line 129 is opened to permit entrance of the Precursor 1 vapor present in expansion volume 134 into process chamber 102, which is at a lower pressure. Valves 132 and 138 are controlled by the programmable process control system 176. A vacuum purge valve 133 is tapped between the fill valve 132 and the expansion volume 134, and controls exposure to the vacuum source 115 to enable purging of the expansion volume.

A Precursor 2 storage container 140 contains coating reactant Precursor 2, which may be heated using heater 142 to provide a vapor, as necessary. As previously mentioned, Precursor 2 transfer line 141 and expansion volume 146 internal surfaces are heated as necessary to maintain Precursor 2 in a vaporous state, thereby avoiding condensation. A fill valve 144 and isolation valve 143 are present on transfer line 141 between Precursor 2 storage container 146 and Precursor 2 expansion volume 146, where the Precursor 2 vapor is permitted to accumulate until a nominal, specified pressure is measured at pressure indicator 148. Fill valve 141 is in a normally-closed position and returns to that position once the specified pressure is reached in Precursor 2 expansion volume 146. At the time the Precursor 2 vapor in expansion volume 146 is to be released, valve 150 on transfer line 141 is opened to permit entrance of the Precursor 2 vapor present in expansion volume 146 into process chamber 102, which is at a lower pressure. Valves 144 and 150 are controlled by programmable process control system 176. A vacuum purge valve 145 is tapped between the fill valve 144 and the expansion volume 146, and controls exposure to the vacuum source 115 to enable purging of the expansion volume.

A Precursor 3 storage container 160 contains coating reactant Precursor 3, which may be heated using heater 162 to provide a vapor, as necessary. Precursor 3 transfer line 161 and expansion volume 170 internal surfaces are heated as necessary to maintain Precursor 3 in a vaporous state, thereby avoiding condensation. A fill valve 166 and isolation valve 164 are present on transfer line 161 between Precursor 3 storage container 160 and Precursor 3 expansion volume 170, where the Precursor 3 vapor is permitted to accumulate until a nominal, specified pressure is measured at pressure indicator 172. Fill valve 166 is in a normally-closed position and returns to that position once the specified pressure is reached in Precursor 3 expansion volume 170. At the time the Precursor 3 vapor in expansion volume 170 is to be released, valve 150 on transfer line 141 is opened to permit entrance of the Precursor 3 vapor present in expansion volume 170 into process chamber 102, which is at a lower pressure. Valves 166 and 150 are controlled by programmable process control system 176. A vacuum purge valve 168 is tapped between the fill valve 166 and the expansion volume 170, and controls exposure to the vacuum source 115 to enable purging of the expansion volume.

During formation of a coating (not shown) on a surface 105 of substrate 106, at least one incremental addition of vapor equal to the expansion volume 122 of the catalyst 154, or the expansion volume 134 of the Precursor 1, or the expansion volume 146 of Precursor 2, or the expansion volume 170 of Precursor 3, may be added to process chamber 102. The total amount of vapor added is controlled by both the adjustable volume size of each of the expansion chambers (typically 50 cc up to 1,000 cc) and the number of vapor injections (doses) into the reaction chamber. Further, the process controller 176 may adjust the set pressure for catalyst expansion volume 122, or the set pressure for Precursor 1 expansion volume 134, or the set pressure for Precursor 2 expansion volume 146, or the set pressure for Precursor 3 expansion volume 170, to adjust the amount of the catalyst or reactant added to any particular step during the coating formation process. This ability to fix precise amounts of catalyst and coating reactant precursors dosed (charged) to the process chamber 102 at any time during the coating formation enables the precise addition of quantities of precursors and catalyst at precise timing intervals, providing not only accurate dosing of reactants and catalysts, but repeatability in terms of time of addition.

This system provides a very inexpensive, yet accurate method of adding vapor phase precursor reactants and catalyst to the coating formation process, despite the fact that many of the precursors and catalysts are typically relatively non-volatile materials. In the past, flow controllers were used to control the addition of various reactants; however, these flow controllers may not be able to handle some of the precursors used for vapor deposition of coatings, due to the low vapor pressure and chemical nature of the precursor materials. The rate at which vapor is generated from some of the precursors is generally too slow to function with a flow controller in a manner which provides availability of material in a timely manner for the vapor deposition process.

The present system allows for accumulation of the vapor into an adequate quantity which can be charged (dosed) to the reaction. In the event it is desired to make several doses during the progress of the coating deposition, the system can be programmed to do so, as described above. Additionally, adding of the reactant vapors into the reaction chamber in controlled aliquots (as opposed to continuous flow) greatly reduces the amount of the reactants used and the cost of the coating process.

Additional details regarding the vapor deposition system may be found in U.S. patent application Ser. No. 10/759,857, entitled “Apparatus and Method for Controlled Application of Reactive Vapors to Produce Thin Films and Coatings,” filed Jan. 17, 2004, the disclosure of which is herein incorporated by reference in its entirety for all purposes. Examples of systems which may employ the methods and apparatus described herein include the MVD300 and MVD4500 molecular vapor deposition systems sold by Applied Microstructures, Inc., of San Jose, Calif.

The aforementioned components of the system 100 which provide for preparation and delivery of either of the catalyst, Precursor 1, Precursor 2 or Precursor 3, to the process chamber 102, define vapor delivery lines (VDL's) for each of the precursors. By way of example, the VDL for Precursor 1 includes the storage container 128, transfer line 129, heater 130, isolation valve 127, fill valve 132, expansion volume 134, pressure indicator 136, and control valve 138. For ease of description, reference is made to the VDL components for Precursor 1. However, it will be understood that the concepts described herein may be equally applied across the VDL's of each of the catalyst, Precursor 1, Precursor 2, Precursor 3 as well as others not shown.

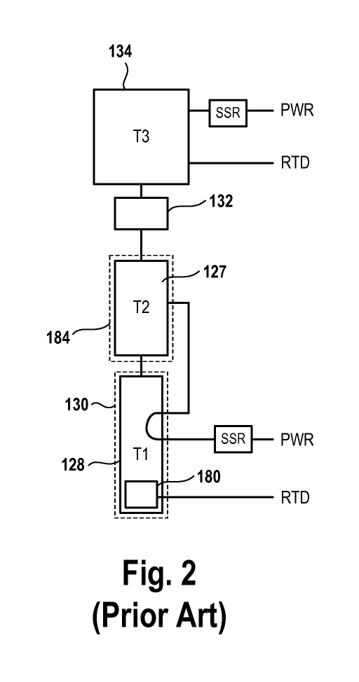

FIG. 2 is a schematic of a conventional vapor delivery line for delivering a precursor vapor to a process chamber. In the illustrated vapor delivery line, the precursor container 128, isolation valve 127, and expansion volume 134 are shown having respective temperatures T1, T2, and T3. As has been noted, the precursor material is generally provided in liquid form in the precursor container 128, which is heated to increase the rate of generation of a vapor of the precursor. The flow of the precursor vapor into the expansion volume 134 is controlled by the fill valve 132 as previously described.

In general, it is desirable for the temperature of the isolation valve T2 to be greater than the temperature of the precursor container T1, to prevent condensation from occurring in the isolation valve 127 when the precursor vapor flows through this valve. Condensation in the isolation valve 127 can result in an increase in the amount of time required to fill the expansion volume 134 to the nominal desired pressure, as precursor material is not directly deposited into the expansion volume 134, but is instead condensed and then re-vaporized within the isolation valve.

For similar reasons, it is generally desirable to maintain expansion volume 134 at a temperature T3 that is greater than the temperature T2 of the control valve 132, to prevent condensation of the precursor vapor from occurring when it enters the expansion volume 134. Thus, it is desirable for the temperatures of the precursor container 128, isolation valve 127, and expansion volume 134 to have a relationship such that T1<T2<T3.

It is noted that the higher the temperature T2 of the isolation valve, then the higher the temperature T3 of the expansion volume must be in order to maintain the proper temperature relationship. Further, if T2 is too high, then this can negatively impact the accuracy of filling the expansion volume because a higher T2 will cause the rate at which precursor vapor flows into the expansion volume to increase. Such a scenario makes it more difficult to accurately meter the appropriate amount of precursor vapor into the expansion volume, and generally increases the likelihood of overfilling the expansion volume beyond the desired molar quantity of precursor vapor due to the speed at which precursor vapor flows into the expansion volume.

One possible strategy for producing the appropriate temperature relationships amongst the precursor container, the control valve, and the expansion volume, is to heat only the precursor container and the expansion volume, allowing the control valve which is situated between them to be passively heated by virtue of its in-line connection to each of the precursor container and the expansion volume. However, to achieve the desired relationship of T1<T2<T3 in such a setup would require complex and special design considerations for the vapor delivery apparatus taking into account any mechanisms effecting heat transfer amongst the precursor container, the control valve, and the expansion volume. Once implemented, such an arrangement would be inflexible, providing no direct control of the temperature of the control valve.

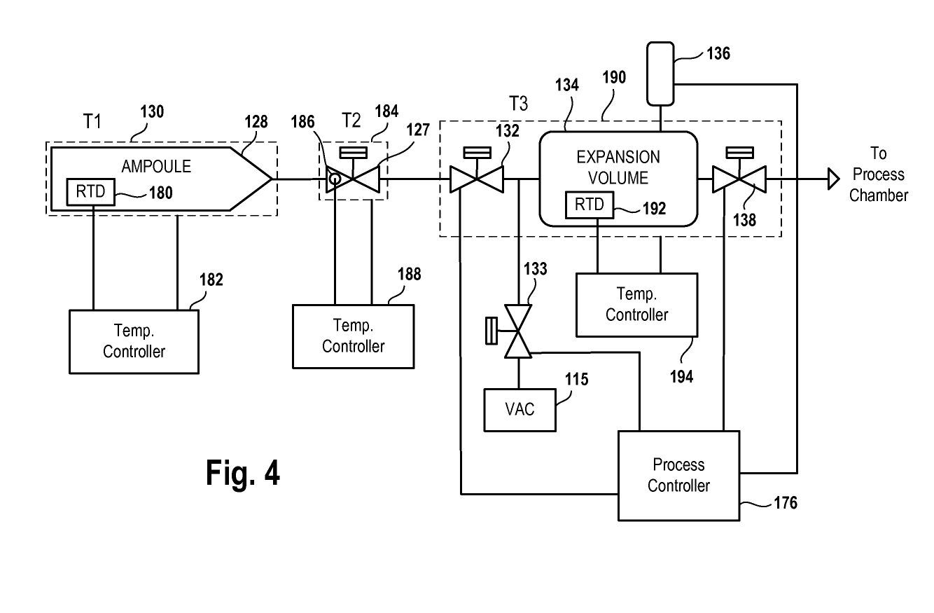

Another possible strategy for achieving the desired temperature relationship of T1<T2<T3, as illustrated at FIG. 2, includes a heater 130 provided for heating the precursor storage container 128, and an additional heater 184 is provided for heating the isolation valve 127. The heater 184 may be configured as a slave heater to the heater 130, connected in series so that heater 184 receives a preset fraction of the power delivered to the heater 130. A temperature controller 182 (shown at FIG. 4) reads the temperature of the precursor storage container 128 via a temperature detector 180 (e.g. a resistance temperature detector (RTD)) and controls the power delivery to the heater 130 so as to achieve a predefined temperature for the precursor storage container 128. Heater 130, which heats the precursor storage container 128, is connected in series to heater 184, which heats the isolation valve 127. Thus, as precursor storage container 128 is heated, isolation valve 127 is also heated.

The above-described configuration has been found to provide a relatively stable temperature for the isolation valve 127 when the size of the precursor storage container 128 is relatively small, such as on the order of approximately 50 cubic centimeters (50 cc). However, because the heat capacity of the precursor storage container 127 decreases as the chemical Precursor 1 is used up, the amount of power required to maintain the storage container 127 at temperature T1 will decrease over time. This means that with the above-described setup, the amount of power supplied to the isolation valve's heater 184 will also decrease over time. However, because the heat capacity of the isolation valve 127 does not change, the result is that the temperature of the isolation valve 127 decreases as the Precursor 1 in the precursor storage container 128 is consumed.

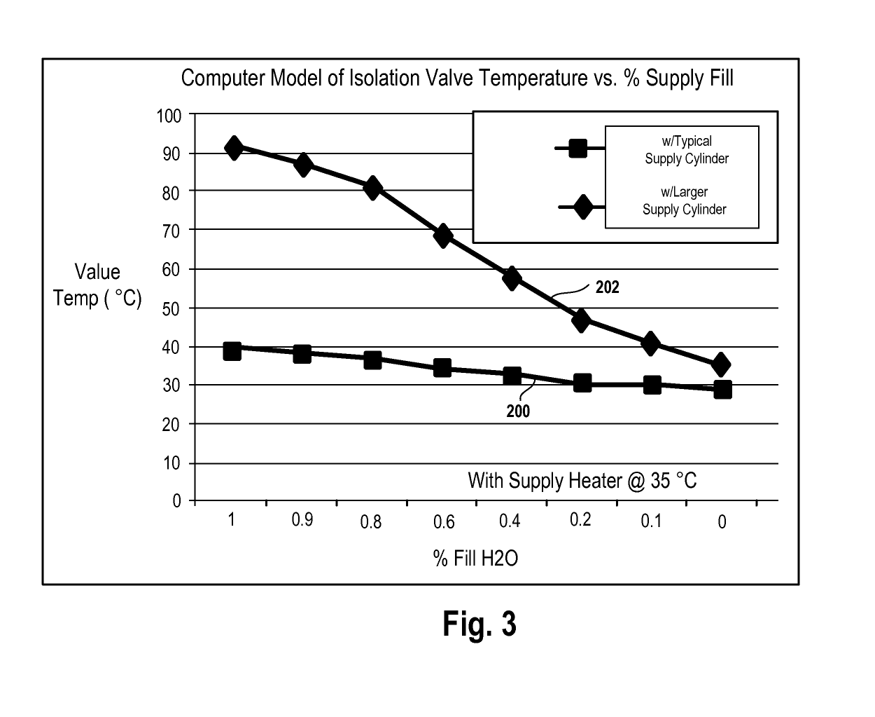

FIG. 3 shows the effect of series connection in a design like the one shown at FIG. 2, illustrating the problem which results from trying to increase supply cylinder size with a series connection. More specifically, FIG. 3 illustrates the results of a computer simulation modeling the temperature of the isolation valve as a function of the percentage fill of the precursor storage container. The results shown are indicative of a system having two heaters connected in series for heating the precursor storage container and the isolation valve. The precursor material is water and the precursor storage container is heated and maintained at 35 degrees Celsius. The curve 200 illustrates the change in temperature of the isolation valve when the precursor storage container is a 50 cc cylinder. The curve 202 illustrates the change in temperature of the isolation valve when the precursor storage container is a 300 cc cylinder. As can be seen, there is a dramatic difference in the change in temperature of the isolation valve depending upon whether the 50 cc cylinder or the 300 cc cylinder is utilized. For the 50 cc cylinder, the change in temperature of the isolation valve between 80% and 10% fill is approximately seven degrees. Whereas for the 300 cc cylinder, the change in temperature of the isolation valve between 80% and 10% fill is approximately 40 degrees.

Such large changes in temperature of the isolation valve as are seen when using the 300 cc cylinder, and even the smaller changes seen when using the 50 cc cylinder, can be problematic for several reasons. The drop in temperature of the isolation valve as the precursor is used up may eventually result in the temperature of the isolation valve becoming close to or less than the temperature of the cylinder, so that condensation occurs in the isolation valve. Further, the high temperatures and temperature fluctuations to which the isolation valve may be subjected may additionally stress the isolation valve and ultimately reduce its lifetime. Large changes in the temperature of the isolation valve can also impact the fill time consistency of the expansion volume, as fill time generally decreases as the temperature of the isolation valve increases. Moreover, high temperatures at the isolation valve may require additionally higher temperatures to be maintained at the expansion volume to prevent condensation in the expansion volume. Condensation in the expansion volume would detrimentally affect the accuracy of a determination of the accumulated molar quantity of precursor that is based on detected pressure within the expansion volume, and would further impede the vapor delivery process as a wait would be required for the condensed precursor to re-vaporize. Increased temperatures at the isolation valve may also result in inaccurate filling of the expansion volume due to the inflow of precursor vapor into the expansion volume being too fast for accurate control.

However, it is generally desirable to utilize a larger precursor storage container, so that more precursor is available for use before one is required to refill or change the precursor storage container. Refilling or changing the precursor storage container results in downtime of the vapor deposition system, as the system must be taken offline, the precursor storage container changed, and the system prepared for production again. The result is loss of production time and increased cost of ownership. Further, when smaller precursor storage containers are employed, more precursor storage containers and isolation valves are purchased for the same amount of precursor as compared to larger precursor storage containers, which also increases the cost of operation.

FIG. 4 illustrates a schematic of a vapor delivery apparatus for providing precursor vapor to a process chamber for vapor deposition. In the illustrated embodiment, the precursor storage container 128, the isolation valve 127, and the expansion volume 134 are shown having temperatures T1, T2, and T3, respectively. A temperature detector 180 (e.g., an RTD) detects the temperature of the precursor storage container 128. Based on the detected temperature, the temperature controller 182 controls the heater 130 to maintain the precursor storage container at the predefined temperature T1. By way of example, the temperature controller 182 may include a solid state relay or other type of temperature control mechanism capable of maintaining precursor storage container at a constant temperature.

A separate temperature detector 186 (e.g., a thermocouple (TC) or RTD) is coupled to isolation valve 127 to detect the temperature of the isolation valve 127. The temperature controller 188 reads the temperature of the isolation valve 127 from the temperature detector 186 and controls the heater 184 so as to heat the isolation valve at a constant predefined temperature T2.

The expansion volume 134 also has an associated heater 190 and a temperature detector 192 (e.g., an RTD). The temperature controller 194 monitors the temperature of the expansion volume 134 via the temperature detector 192, and controls the heater 190 so as to maintain the expansion volume (as well as the fill valve 132 and the delivery valve 138) at the predefined temperature T3.

The isolation valve 127 is manually controlled and generally left open during processing operations. The fill valve 132, delivery valve 138, and vacuum purge valve 133 are controlled by the process controller 176. In some embodiments, the fill valve 132, delivery valve 138, and vacuum purge valve 133 are pneumatically actuated.

The configuration of the vapor delivery apparatus shown in FIG. 4 provides for independent temperature control of the precursor storage container 128, the isolation valve 127, and the expansion volume 134. In particular, the independent temperature control of the isolation valve 127 provides for the temperature of the isolation valve to be maintained at a constant predefined temperature T2 despite changes in the heat capacity of the precursor storage container 128 which occur as the precursor material within the precursor storage container 128 is used up over time. This provides for consistent fill times of the expansion volume throughout the usage period of the precursor storage container 128, and enables usage of larger sized precursor storage containers without adverse effects that would otherwise result from temperature fluctuations of the isolation valve.

The aforementioned precursor storage container can be a cylinder, ampoule, or any other type of container capable of containing a precursor material and to which an isolation valve may be connected. Broadly speaking, the volume of the precursor storage container ranges from about 50 cc to about 5000 cc (5 liters), though volumes greater that 5000 cc or less than 50 cc are also contemplated. Likewise, the volume of the expansion volume may vary depending upon the application desired. In some embodiments, the volume of the expansion volume is approximately 600 cc. In other embodiments, the volume of the expansion volume may be between about 100 cc and 10,000 cc (10 liters).

Fill times for a 600 cc expansion volume typically range from about two to 20 seconds. In some embodiments, fill times range between about 5 to 15 seconds. The amount of power applied to heat a 300 cc precursor storage container is typically in the range of about 40 to 120 W. The specific amount of power applied to heat the precursor storage container at any given moment will of course depend upon the heat capacity of the container, which in turn is partly based on the amount of precursor remaining The amount of power applied to heat the isolation valve is typically in the range of about 10 to 40 W.

It will appreciated by those skilled in the art that the various components utilized for temperature detection, heating, and control of heating may vary in accordance with various embodiments of the invention. For example, the heating devices utilized to heat any of the precursor storage container, isolation valve, or expansion volume can include heating jackets, cartridge heaters, lamp heaters, etc. The temperature detectors can be an RTD, a thermocouple, or other temperature detection device capable of integration in an automated system. The temperature controllers can include various types of temperature control and feedback mechanisms for facilitating provision of appropriate amounts of power to heating devices so as to maintain constant temperatures, and may include solid state relays, proportional integral derivative controllers (PID controllers), DC voltage controllers/regulators, etc.

Exemplary heating and control systems are provided by way of example only, and not by way of limitation. For example, in one embodiment a heating and control configuration may include a heating jacket utilizing AC power with a PID/SSR using a RTD/TC for temperature measurement. In another embodiment, a cartridge heater with AC power is utilized in conjunction with a PID/SSR control using a RTD/TC for temperature measurement. In another embodiment, a cartridge heater with DC power is utilized in conjunction with a DC voltage controller/regulator using a RTD/TC for temperature measurement. In yet another embodiment, a lamp heater is utilized in conjunction with a RTD/TC for temperature measurement. The foregoing examples of heating and control systems are provided by way of example only, as any suitable components may be utilized to provide for heating, temperature measurement, and control of the heating in response to the temperature measurement, in accordance with the principles, methods, and apparatus described herein.

Further, though reference is made to the maintenance of various components of the deposition system at a “constant” temperature via such temperature control systems as are described herein, it will be understood by those skilled in the art that in an absolutely strict sense the temperature may actually fluctuate within a small range due to the specific characteristics of the temperature control setup employed. This is because such temperature control systems respond to sensed changes in temperature which deviate from the desired preset temperature, and react accordingly. If the detected temperature drops below the preset temperature, then the heater is controlled to increase the heat applied, whereas if the detected temperature increases above the preset temperature, then the heater is controlled to reduce the heat applied. In this manner, the temperature is controlled and maintained at a “constant” level to a given degree of accuracy as determined by the sensitivity and resolution capabilities of the components utilized for temperature measurement and control.

The apparatus thus described includes both an isolation valve and a fill valve. In an alternative embodiment, the isolation valve and the fill valve can be replaced with a single hybrid control valve which serves the function of both the isolation valve and fill valve. In other words, the hybrid control valve can be automatically controlled (e.g., via pneumatic actuation) by the process controller, but can also be manually closed or locked to permit transport of the precursor storage container without exposing the contents of the precursor storage container to atmosphere. In embodiments employing such a hybrid control valve, the aforementioned temperature detection and control mechanisms can be applied to the hybrid control valve to maintain the hybrid control valve at the constant temperature T2.

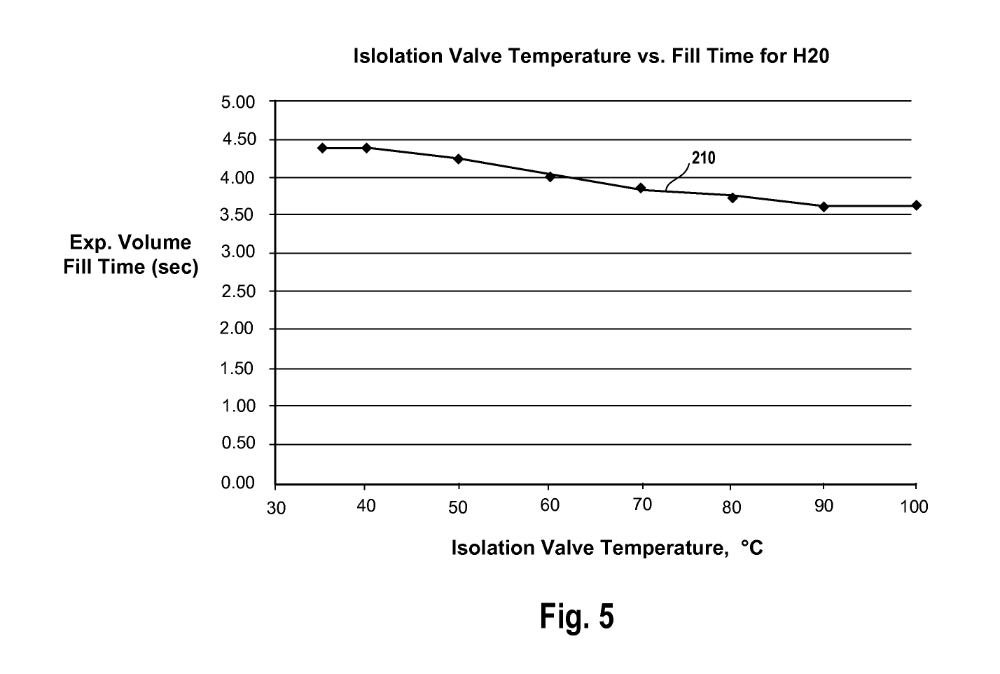

FIG. 5 is a graph illustrating fill time of the expansion volume as a function of isolation valve temperature. The precursor storage container is heated at 35 degrees Celsius, and the expansion volume is heated at 100 degrees Celsius. The precursor material is water. As shown by the curve 210, as the temperature of the isolation valve increases, the fill time of the expansion volume decreases. As has been noted, if the fill time decreases to too great an extent, then it becomes increasingly difficult to accurately fill the expansion volume with the desired amount of precursor vapor. On the other hand, if fill time increases to too great an extent, then throughput is reduced. The presently described embodiments facilitate independent control of the isolation valve temperature, so that fill time is maintained at a consistent level, providing for repeatable performance of the vapor delivery system.

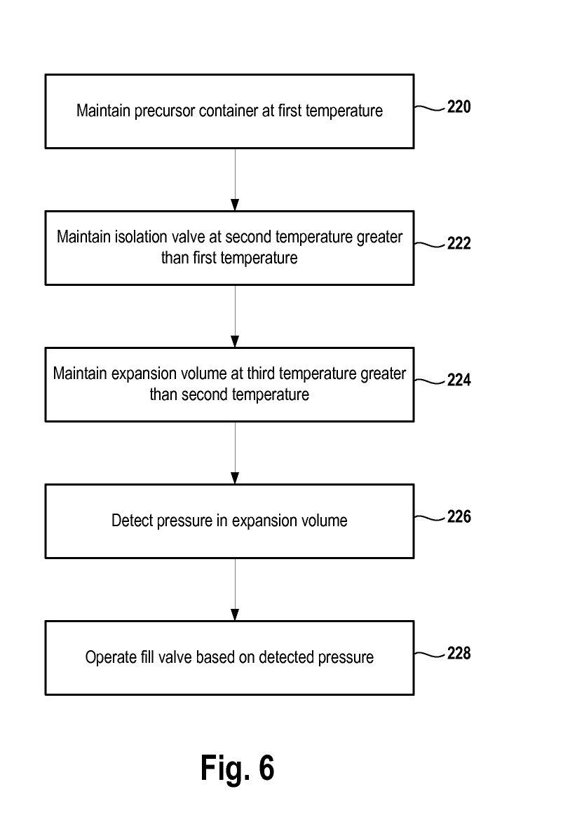

FIG. 6 illustrates a method for preparing a precursor vapor for a deposition process, in accordance with embodiments of the invention. At method operation 220, a precursor container is maintained at a first temperature to generate the vapor precursor from a liquid or solid precursor. Maintenance of the precursor container at the first temperature generally includes detecting the temperature of the precursor container, and applying power to a first heating device based on the detected temperature of the precursor container. At method operation 222, an isolation valve is maintained at a second temperature greater than the first temperature, the isolation valve being coupled to the precursor container. Maintenance of the isolation valve at the second temperature generally includes detecting the temperature of the isolation valve, and applying power to a second heating device based on the detected temperature of the isolation valve. At method operation 224, an expansion volume is maintained at a third temperature greater than the second temperature. Maintenance of the expansion volume at the third temperature typically includes detecting the temperature of the expansion volume, and applying power to a third heating device based on the detected temperature of the expansion volume. At method operation 226, the pressure in the expansion volume is detected. At method operation 228, a fill valve is operated based on the detected pressure in the expansion volume to control flow of the vapor precursor from the precursor container into the expansion volume to accumulate a specific quantity of the vapor precursor. The fill valve is coupled to the isolation valve and to the expansion volume.

Embodiments of the present invention provide methods and apparatus for independent temperature control of the isolation valve, in conjunction with independent temperature control of each of the precursor storage container and the expansion volume. The presently described methods and apparatus enable a proper temperature relationship to be maintained amongst the precursor storage container, the isolation valve, and the expansion volume, so that condensation is avoided in the vapor delivery apparatus. Large fluctuations in the temperature of the isolation valve are avoided, which helps to preserve the lifetime of the isolation valve, while also providing for more consistent fill times of the expansion volume. These benefits also simplify the process of automating the repeated filling of the expansion volume with precursor vapor and subsequent delivery to the process chamber, as compensating measures for temperature fluctuations of the isolation valve are no longer required. Furthermore, greater accuracy in filling the expansion volume is achieved in a repeatable manner because the fill time is maintained in a consistent manner.

Additionally, the presently described embodiments enable different sizes of the precursor storage container to be utilized with the vapor deposition system, without requiring extensive reconfiguration to accommodate the different sized containers. The specific size of the precursor storage container that is best suited for a given application will depend on several factors, such as the lifetime of the chemical precursor, the amount of precursor consumed in each deposition operation, the number of deposition operations required per unit time (rate of deposition operations) by the operator of the deposition system, etc. For example, a research institution may only require a relatively limited number of deposition operations for a given precursor material, and therefore utilize a smaller sized precursor storage container. On the other hand, a production fab may require a very large number of deposition operations on an ongoing basis, and therefore utilize a much larger sized precursor storage container, so that changeouts of the precursor storage container are held to a minimum. The present embodiments provide for flexibility in the size of the precursor storage container that can be utilized with the same deposition system, without requiring extensive modification or reconfiguration of the deposition system to accommodate the different storage container sizes.

Embodiments of the present invention provide greatly improved methods and apparatus for vapor delivery and vapor deposition. It is to be understood that the above description is intended to be illustrative and not restrictive. Many embodiments and variations of the invention will become apparent to those of skill in the art upon review of this disclosure. Merely by way of example a wide variety of process times, process temperatures and other process conditions may be utilized, as well as a different ordering of certain processing steps. The scope of the invention should, therefore, be determined not with reference to the above description, but instead should be determined with reference to the appended claims along with the full scope of equivalents to which such claims are entitled.

The explanations and illustrations presented herein are intended to acquaint others skilled in the art with the invention, its principles, and its practical application. Those skilled in the art may adapt and apply the invention in its numerous forms, as may be best suited to the requirements of a particular use. Accordingly, the specific embodiments of the present invention as set forth are not intended as being exhaustive or limiting of the invention.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. A vapor delivery apparatus for providing a precursor vapor for a vapor deposition process, comprising:
a precursor container for holding a liquid or solid precursor;
a first temperature control assembly for maintaining the precursor container at a first temperature to generate a vapor precursor from the liquid or solid precursor;
an isolation valve coupled to the precursor container;
an expansion volume for accumulating a specific quantity of the vapor precursor;
a fill valve coupled to each of the isolation valve and the expansion volume, the fill valve controlling flow of the vapor precursor from the precursor container into the expansion volume; and
a second temperature control assembly for maintaining the isolation valve at a second temperature greater than the first temperature.

2. The vapor delivery apparatus of claim 1, wherein
the first temperature control assembly includes a first heating device for heating the precursor container, a first temperature detector for detecting temperature of the precursor container, and a first controller configured to apply power to the first heating device based on the detected temperature of the precursor container to maintain the precursor container at the first temperature; and
the second temperature control assembly includes a second heating device for heating the isolation valve, a second temperature detector for detecting temperature of the isolation valve, and a second controller configured to apply power to the second heating device based on the detected temperature of the isolation valve to maintain the isolation valve at the second temperature.

3. The vapor delivery apparatus of claim 2, wherein
the first heating device includes a first heater jacket coupled to the precursor container; and
the second heating device includes a second heater jacket coupled to the isolation valve.

4. The vapor delivery apparatus of claim 2, wherein the first temperature detector and the second temperature detector each include either a thermocouple or a resistance temperature detector.

5. The vapor delivery apparatus of claim 2, wherein the first controller and the second controller each include a solid state relay.

6. The vapor delivery apparatus of claim 1, wherein the precursor container defines a volume of about 50 cc to about 5000 cc.

7. The vapor delivery apparatus of claim 1, further comprising:
a third temperature control assembly for maintaining the expansion volume at a third temperature greater than the second temperature.

8. The vapor delivery apparatus of claim 7, wherein the third temperature control assembly includes a third heating device for heating the expansion volume, a third temperature detector for detecting temperature of the expansion volume, and a third controller configured to apply power to the third heating device based on the detected temperature of the expansion volume to maintain the expansion volume at the third temperature.

9. The vapor delivery apparatus of claim 1, further comprising:
a pressure sensor for detecting pressure in the expansion volume; and
a valve controller configured to operate the fill valve based on the detected pressure in the expansion volume to accumulate the specific quantity of the vapor precursor in the expansion volume.

10. The vapor delivery apparatus of claim 1, further comprising:
a delivery valve coupled to the expansion volume, the delivery valve controlling flow of the specific quantity of the vapor precursor from the expansion volume into a process chamber.

11. A method for preparing a precursor vapor for a deposition process, comprising:
maintaining a precursor container at a first temperature to generate the vapor precursor from a liquid or solid precursor;
maintaining an isolation valve at a second temperature greater than the first temperature, the isolation valve coupled to the precursor container;
detecting pressure in an expansion volume; and
operating a fill valve based on the detected pressure in the expansion volume to control flow of the vapor precursor from the precursor container into the expansion volume to accumulate a specific quantity of the vapor precursor, the fill valve being coupled to the isolation valve and to the expansion volume.

12. The method of claim 11, wherein
maintaining the precursor container at the first temperature includes detecting temperature of the precursor container, and applying power to a first heating device based on the detected temperature of the precursor container; and
maintaining the isolation valve at the second temperature includes detecting temperature of the isolation valve, and applying power to a second heating device based on the detected temperature of the isolation valve.

13. The method of claim 11, further comprising:
maintaining the expansion volume at a third temperature greater than the second temperature.

14. The method of claim 13, wherein maintaining the expansion volume at the third temperature includes detecting temperature of the expansion volume, and applying power to a third heating device based on the detected temperature of the expansion volume.

15. The method of claim 11, further comprising:
operating a delivery valve to control flow of the specific quantity of the vapor precursor from the expansion volume into a process chamber.

16. An atomic layer deposition system, comprising:
a precursor container for holding a liquid or solid precursor;
a first temperature control assembly for maintaining the precursor container at a first temperature to generate a vapor precursor from the liquid or solid precursor;
an expansion volume for accumulating a specific quantity of the vapor precursor;
a first control valve disposed between the precursor container and the expansion volume, the first control valve controlling flow of the vapor precursor from the precursor container into the expansion volume;
a second temperature control assembly for maintaining the control valve at a second temperature greater than the first temperature;
a third temperature control assembly for maintaining the expansion volume at a third temperature greater than the second temperature;
a pressure sensor for detecting pressure in the expansion volume;
a valve controller configured to operate the control valve based on the detected pressure in the expansion volume to accumulate the specific quantity of the vapor precursor in the expansion volume;
a process chamber; and
a second control valve disposed between the expansion volume and the process chamber, the second control valve controlling flow of the specific quantity of the vapor precursor from the expansion volume into a process chamber.

17. The system of claim 16, wherein
the first temperature control assembly includes a first heating device for heating the precursor container, a first temperature detector for detecting temperature of the precursor container, and a first controller configured to apply power to the first heating device based on the detected temperature of the precursor container to maintain the precursor container at the first temperature;
the second temperature control assembly includes a second heating device for heating the first control valve, a second temperature detector for detecting temperature of the first control valve, and a second controller configured to apply power to the second heating device based on the detected temperature of the first control valve to maintain the first control valve at the second temperature; and
the third temperature control assembly includes a third heating device for heating the expansion volume, a third temperature detector for detecting temperature of the expansion volume, and a third controller configured to apply power to the third heating device based on the detected temperature of the expansion volume to maintain the expansion volume at the third temperature.

18. The system of claim 17, wherein
the first heating device includes a first heater jacket coupled to the precursor container; and
the second heating device includes a second heater jacket coupled to the first control valve.

19. The system of claim 17, wherein each of the first, second, and third temperature detectors includes either a thermocouple or a resistance temperature detector.

20. The system of claim 16, wherein the precursor container defines a volume of about 50 cc to about 5,000 cc.
